(19) United States
(12) Patent Application Publication
(10) Pub. No.: US 2017/0212384 A1
(43) Pub. Date: Jul. 27, 2017

(54) DISPLAY DEVICE AND MANUFACTURING METHOD THEREFOR

(71) Applicants: BOE TECHNOLOGY GROUP CO., LTD., Beijing (CN); HEFEI BOE OPTOELECTRONICS TECHNOLOGY CO., LTD., Hefei City, Anhui (CN)

(72) Inventors: Junsheng CHEN, Beijing (CN); Dong CHEN, Beijing (CN); Hui WANG, Beijing (CN)

(21) Appl. No.: 15/326,210

(22) PCT Filed: Jul. 7, 2015
(86) PCT No.: PCT/CN2015/083426

§ 371 Date: Jan. 13, 2017

(30) Foreign Application Priority Data
Jan. 27, 2015 (CN) 201510041737.2

(51) Int. Cl. G02F 1/1335; H01L 51/52; H01L 27/32; G02F 1/1333; G06F 3/041

(52) U.S. Cl. CPC G02F 1/133528; G02F 1/13338; G02F 1/133553; G02F 1/133502; G06F 3/041; H01L 27/323; H01L 51/5281; G02F 2202/28; G02F 2201/34; G06F 2203/04103; H01L 2227/323

(57) ABSTRACT

A display device and a manufacturing method therefor are provided. The display device includes a display panel. At least one side of the display panel is provided with a polarizer. An optical functional layer is disposed between the at least one polarizer and the display panel. In this way, the display device and the manufacturing method therefor can effectively solve the problem of a bubble defect due to the disposal of the optical functional layer between protection glass and the display panel.

### TECHNICAL FIELD

Embodiments of the present invention relate to a display device and a manufacturing method thereof.

### BACKGROUND

Display devices mainly include liquid crystal display devices and Organic Light-Emitting Diode (OLED) display devices. In the practical application, light emitting surface of a conventional display device tends to experience badness such as glare due to the influence of light from external environment, which would have a strong impact on the user's viewing experience. In order to overcome various optical badness including glare, various optical functional layers are generally formed on a surface of a display device.

Particularly, for a liquid crystal display device, as the core component for the liquid crystal display device, the liquid crystal panel mainly includes a color filter substrate and a Thin Film Transistor (TFT) array substrate assembled to form a cell with each other with a liquid crystal layer formed of liquid crystal material therebetween. Generally, under the action of a voltage, the liquid crystal layer can only rotate polarized light with a certain polarization angle, therefore, in prior art, an upper polarizer sheet and a bottom polarizer sheet are generally attached to the surfaces of upper and bottom glass substrates of the liquid crystal panel. In order to overcome various optical badness including glare, polarizer sheets are generally subjected to different kinds of surface treatments to form optical functional layers with different functions. The specific structure of the polarizer sheet 1 is illustrated in FIG. 1, which includes a polarizing layer 11 for polarization and protecting layers 12 located on both sides of the polarizing layer 11. The optical functional layer 13 is generally made on the protecting layer 12 that is located on the light emitting surface. In the process of assembling the display panel, a layer of protecting glass 2 will be attached to a surface of the optical functional layer 13. The surface of the optical functional layer 13 is not completely flat, especially when the optical functional layer 13 includes an anti-glare layer that reflects ambient light mainly utilizing the diffuse reflection principle. Thus, since the surface is relatively coarse, bubble badness will occur when attaching the cover glass 2 and the polarizer sheet 1, which severely impacts the quality and display effect of the display device product. Not only liquid crystal display devices, but also OLED display devices suffer similar problems.

### SUMMARY

An embodiment of the invention provides a display device, comprising a display panel provided with a polarizer sheet on at least one side thereof, wherein an optical functional layer is disposed between at least one polarizer sheet and the display panel.

Another embodiment of the invention provides a manufacturing method of a display device, comprising: forming an optical functional layer on a surface of a side of a polarizer sheet; and attaching the side of the polarizer sheet that is formed with the optical functional layer to a surface of a display panel.

Still another embodiment of the invention provides a manufacturing method of a display device, comprising: forming an optical functional layer on a surface on at least one side of a display panel; and attaching the at least one side of the display panel that is formed with the optical functional layer to a surface of a polarizer sheet.

### BRIEF DESCRIPTION OF THE DRAWINGS

In order to clearly illustrate the technical solution of the embodiments of the invention, the drawings of the embodiments will be briefly described in the following; it is obvious that the described drawings are only related to some embodiments of the invention and thus are not limitative of the invention.

FIG. 1 is a structure diagram of a polarizer sheet in prior art;

FIG. 2 is a structure diagram of a display device provided in an embodiment of the present invention;

FIG. 3 is a structure diagram of another display device provided in an embodiment of the present invention;

FIG. 4 is a top view of a liquid crystal display panel;

FIG. 5 is a structure diagram of another display device provided in an embodiment of the present invention;

FIG. 6 is a flow chart of a manufacturing method of a display device provided in an embodiment of the present invention; and

FIG. 7 is a flow chart of another manufacturing method of a display device provided in an embodiment of the present invention.

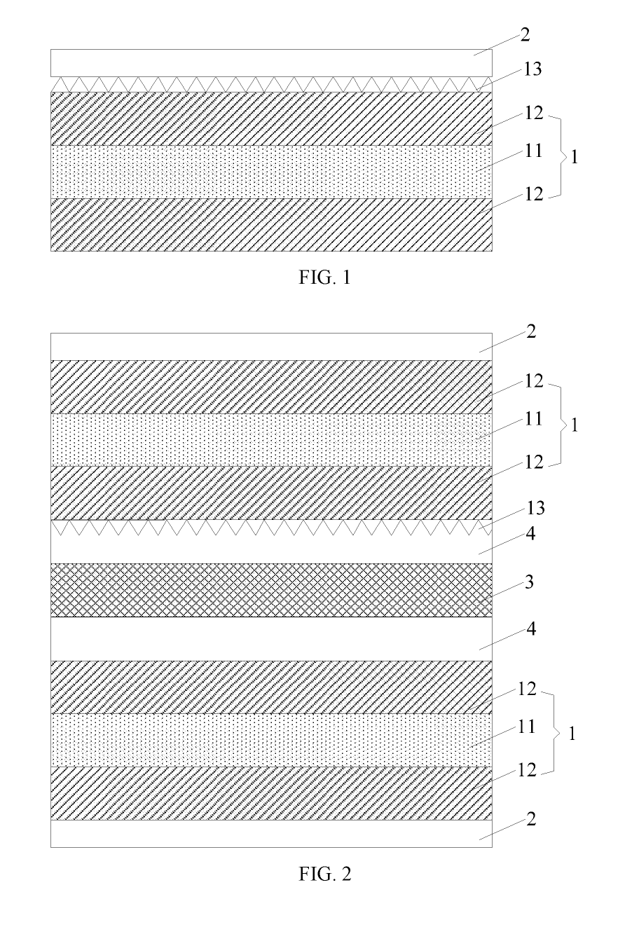

### DETAILED DESCRIPTION

In order to make objects, technical details and advantages of the embodiments of the invention apparent, the technical solutions of the embodiments will be described in a clearly and fully understandable way in connection with the drawings related to the embodiments of the invention. Apparently, the described embodiments are just a part but not all of the embodiments of the invention. All other embodiments obtained by those skilled in the art without any creative labor based on the described embodiments of the present invention belong to the scope of the present invention.

As illustrated in FIG. 2, the display device provided in the embodiment of the present invention includes a display panel 3 provided with a polarizer sheet 1 on at least one side thereof.

An optical functional layer 13 is provided between at least one polarizer sheet 1 and the display panel 3.

The display device provided in the embodiment of the present invention includes a display panel provided with a polarizer sheet, and the optical functional layer is disposed between at least one polarizer sheet and the display panel. With the display device of such a structure, the flatness of the contact surface between the polarizer sheet and the cover glass is guaranteed while overcoming various optical badness including glare, which avoids generation of bubbles, and effectively addresses the problem of bubble occurrence in prior art due to the provision of optical functional layer between the cover glass and the display panel.

It is to be noted that the display device may be ally product or component with display function such as a liquid crystal panel, electronic paper, an OLED panel, a mobile phone, a tablet computer, a TV set, a display, a notebook computer, a digital picture frame, and a navigator. Such a structure of optical functional layer provided in the embodiment of the present invention may be applicable to various known display devices including liquid crystal display panels and OLED display devices.

Furthermore, in the manufacturing process, the optical functional layer 13 may be disposed on a surface of the polarizer sheet 1 and then the side of the polarizer sheet 1 provided with the optical functional layer 13 is attached to the display panel, as illustrated in FIG. 2. The optical functional layer 13 may also be disposed on a surface of the display panel and then the polarizer sheet 1 is attached to the side of the display panel that is provided with the optical functional layer 13.

In an embodiment of the present invention, the optical functional layer 13 includes at least one of an anti-glare layer, a hardened layer and a low reflection layer.

For example, while applied to a liquid crystal display device, the display panel 3 is a liquid crystal display panel. The liquid crystal display panel may be a liquid crystal display panel with any structure in the prior art, which is not limited herein.

Since a liquid crystal display panel generally can only rotate polarized light with a certain polarization angle, in the liquid crystal display device illustrated in FIG. 2, polarizer sheets 1 are disposed on both sides of the liquid crystal display panel and an optical functional layer 13 is disposed between at least one polarizer sheet 1 and the display panel 3.

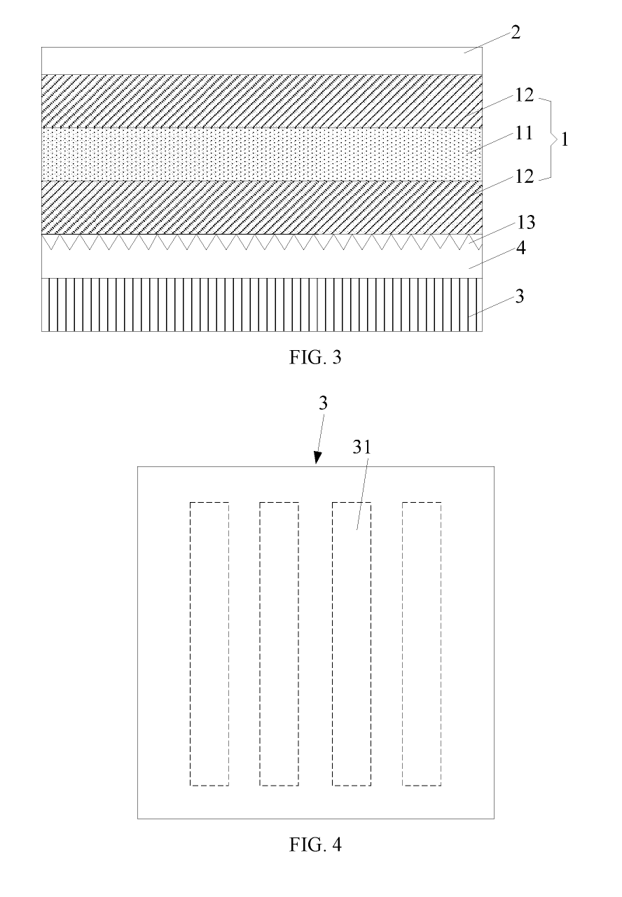

It is to be noted that for the liquid crystal display device, it is possible to dispose optical functional layers between both polarizer sheets located on both sides of the liquid crystal display panel and the liquid crystal panel, and it is also possible to dispose an optical functional layer only between a polarizer sheet on one side and the liquid crystal panel, which is not limited in the present invention. In the liquid crystal display device illustrated in FIG. 3, description is given with respect to an example in which the optical functional layer is disposed on the side of the upper polarizer sheet.

Upon being applied to an OLED display device, the display panel 3 includes an OLED display panel. Similarly to the liquid crystal display device, the OLED display panel may be an OLED display panel with any structure in the prior art, which is not limited herein.

The structure of the OLED display device may be as illustrated in FIG. 3, in which a polarizer sheet 1 may be disposed on a side of the light emitting surface of the OLED display panel and an optical functional layer 13 is disposed between the polarizer sheet 1 and the display panel 3.

Furthermore, a touch unit may further be disposed on a surface on the side of light emitting surface of the display panel 3.

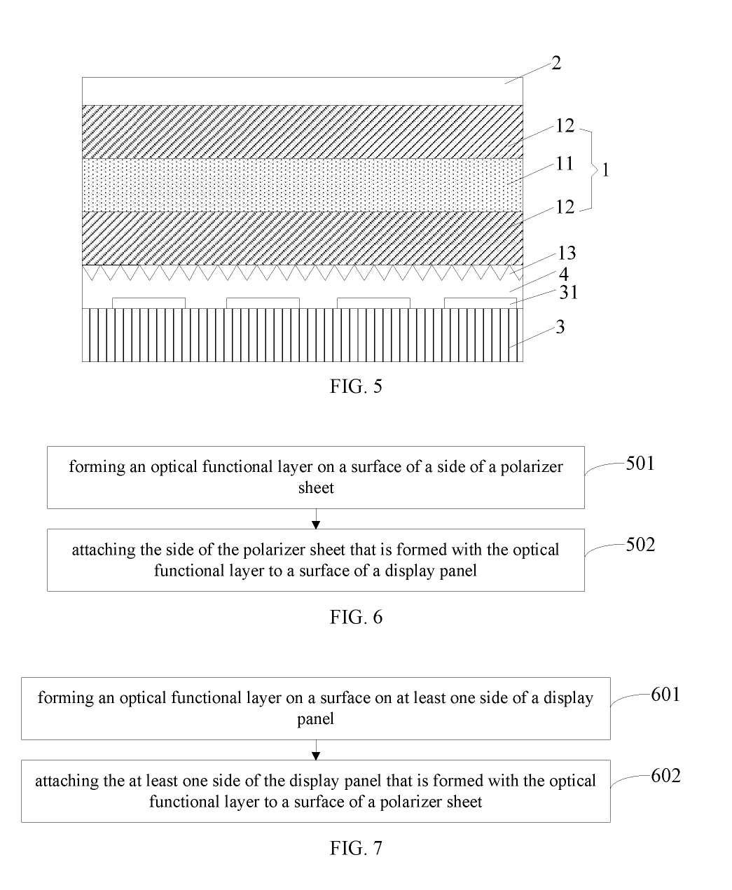

For example, taking a liquid crystal display device as an example, as illustrated in FIG. 4, in order to implement touch function of a terminal mobile phone or a computer, it is possible to coat a layer of metal induction electrode on the glass substrate on the side of light emitting surface of the liquid crystal panel as a touch unit 31 for implementing touch function, which may be arranged into different shapes according to specific product requirements. When the surface of the upper polarizer sheet does not have the optical functional layer for preventing transmitting or reflecting external ambient light, ambient light would enters the liquid crystal screen and is reflected on the metal induction electrode. The light would be reflected outside the liquid crystal screen, and human eyes would see the shape of metal induction electrode from outside the liquid crystal screen. The slight badness is that the shape of induction electrode can be directly seen when the liquid crystal screen is not turned on. A more severe case is that the shape of induction electrode can be seen when the liquid crystal screen is turn on, which would directly impact the image quality of liquid crystal screen. For example, as illustrated in FIG. 5, the touch unit 31 is disposed between the optical functional layer 13 and the display panel 3.

In order to avoid the badness of impacting image quality by metal induction electrode, it is necessary to provide the optical functional layer 13. Such a display device provided in embodiments of the present invention can guarantee the flatness of contact surface between the polarizer sheet and the cover glass, thereby avoiding occurrence of bubbles, while effectively avoiding badness of impacting image quality by metal induction electrode, which effectively addresses the problem of bubble badness between the cover glass and the display panel in prior art due to the provision of optical functional layer.

Furthermore, as illustrated in FIG. 2, the polarizer sheet 1 includes, for example, a polarizing layer 11 and protecting layers 12 on both sides of the polarizing layer

In some examples, the optical functional layer 13 may be integral with the protecting layer 12 in the polarizer sheet 1 that faces the display panel 3.

As illustrated in FIG. 2, the cover glass (cover plate) 2 is disposed on a surface of the polarizer sheet 1 that is away from the display panel 3. In addition, the cover plate 2 is not limited to glass plate, but may be any appropriate transparent plate.

For example, when the optical functional layer 13 is an anti-glare layer, it is possible to obtain the anti-glare layer by patterning the surface of a protecting layer 12 of the polarizer sheet 1 that faces the side of the display panel 3 to obtain coarse surface undulations. Since the anti-glare layer mainly functions to reflect ambient light, the influence on liquid crystal screen images by ambient light is reduced and the image quality of the liquid crystal screen is improved. The anti-glare layer has a surface with coarse and uneven topology and utilizes the diffuse reflection principle. When the ambient light is incident onto the liquid crystal screen, it experiences diffuse reflection at the anti-glare layer, thereby effectively reducing ambient light that enters the liquid crystal screen.

In some examples, the polarizer sheet 1 may be attached to the display panel 3 by curable glue 4. As illustrated in FIG. 2, the cover glass 2 and the polarizer sheet 1 are generally attached together with water-based glue. When the optical functional layer is disposed between the cover glass 2 and the polarizer sheet 1, attachment bubbles would occur due to the poor coating uniformity caused by the small density of the water-based glue. In an embodiment of the present invention, the optical functional layer is disposed between the polarizer sheet and the display panel. Therefore, the cover glass 2 may be attached directly to the polarizer sheet 1 with the water-based glue, thereby avoiding attachment bubbles. In addition, the glue between the polarizer sheet 1 and the display panel may be ultraviolet curable glue. Bubble occurrence between the protecting layer 12 and the curable glue 4 may be avoided by optimizing the manufacturing process of the polarizer sheet 1 due to the large density of curable glue.

An embodiment of the present invention provides a manufacturing method of a display device, as illustrated in FIG. 6, which includes:
step 501, forming an optical functional layer on a surface on a side of the polarizer sheet; and
step 502, attaching the side of the polarizer sheet that is formed with optical functional layer with a surface of the display panel.

In the manufacturing method of the display device provided in the embodiment of the present invention, the display device includes a display panel provided with a polarizer sheet on at least one side thereof, and the optical functional layer is disposed between at least one polarizer sheet and the display panel. With the display device of such a structure, the flatness of the contact surface between the polarizer sheet and the cover glass is guaranteed while overcoming various optical badness including glare, which avoids generation of bubbles, and effectively addresses the problem of bubble occurrence in prior art due to the provision of optical functional layer between the cover glass and the display panel.

It is to be noted that such a structure of optical functional layer provided in the embodiment of the present invention may be applicable to various known display devices including liquid crystal display panels and OLED display devices.

The detail structure that adopts the display device manufactured according to embodiments of the present invention has been described in detail in the above-mentioned embodiments and will not be described any more herein.

For example, the polarizer sheet may include a polarizing layer and protecting layers on both sides of the polarizing layer. Forming the optical functional layer on a surface on a side of the polarizer sheet includes:
patterning the surface of the protecting layer on one side of the polarizer sheet to roughen the surface, thereby obtaining the optical functional layer.

Attaching the side of the polarizer sheet that is formed with the optical functional layer to the surface of the display panel includes:
coating curable glue between the side of the polarizer sheet that is formed with the optical functional layer and the surface of the display panel and curing the curable glue with ultraviolet curing approach for attachment.

In an embodiment of the present invention, the optical functional layer may include at least one of an anti-glare layer, a hardened layer and a low reflection layer.

Alternatively, as illustrated in FIG. 7, the manufacturing method of display device provided in the embodiment of the present invention includes:
step 601, forming an optical functional layer on a surface on at least one side of the display panel; and
step 602, attaching the at least one side of the display panel that is formed with optical functional layer with a surface of the polarizer sheet.

In the manufacturing method of the display device provided in the embodiment of the present invention, the display device includes a display panel provided with a polarizer sheet, and the optical functional layer is disposed between at least one polarizer sheet and the display panel. With the display device of such a structure, the flatness of the contact surface between the polarizer sheet and the cover glass is guaranteed while overcoming various optical badness including glare, which avoids generation of bubbles, and effectively addresses the problem of bubble occurrence in prior art due to the provision of optical functional layer between the cover glass and the display panel.

It is to be noted that such a structure of optical functional layer provided in the embodiment of the present invention may be applicable to various known display devices including liquid crystal display panels and OLED display devices.

The detailed structure that adopts the display device manufactured according to embodiments of the present invention has been described in detail in the above-mentioned embodiments and will not be described any more herein.

For example, attaching the at least one side of the display panel that is formed with optical functional layer with a surface of the polarizer sheet includes:
coating curable glue between the at least one side of the display panel that is formed with the optical functional layer and the surface of the polarizer sheet and curing the curable glue with ultraviolet curing approach for attachment.

In an embodiment of the present invention, the optical functional layer may include at least one of an anti-glare layer, a hardened layer and a low reflection layer.

What are described above is related to the illustrative embodiments of the disclosure only and not limitative to the scope of the disclosure; the scopes of the disclosure are defined by the accompanying claims.

The present application claims priority of China Patent application No. 201510041737.2 filed on Jan. 27, 2015, the content of which is incorporated in its entirety as part of the present application by reference herein.

1. A display device, comprising a display panel provided with a polarizer sheet on at least one side thereof, wherein an optical functional layer is disposed between at least one polarizer sheet and the display panel.

2. The display device of claim 1, wherein the display panel comprises a liquid crystal display panel; the liquid crystal display panel is provided with polarizer sheets on both sides, and the optical functional layer is disposed between the polarizer sheet on at least one side of the display panel and the display panel.

3. The display device of claim 1, wherein the display panel comprises an OLED display panel; the OLED display panel is provided with the polarizer sheet on a light emitting side, and the optical functional layer is disposed between the polarizer sheet and the display panel.

4. The display device of claim 1, wherein the display panel is provided with a touch unit, the polarizer sheet and the optical functional layer on a light emitting side, and the touch unit is disposed between the optical functional layer and the display panel.

5. The display device of claim 4, wherein the touch unit comprises a plurality of metal induction electrodes.

6. The display device of claim 1, wherein the polarizer sheet comprises a polarizing layer and protecting layers on both sides of the polarizing layer.

7. The display device of claim 6, wherein the optical functional layer and the protecting layer on a side of the polarizer sheet that faces the display panel are an integral structure.

8. The display device of claim 1, wherein the polarizer sheet is attached to the display panel by curable glue.

9. The display device of claim 1, wherein the optical functional layer comprises at least one of an anti-glare layer, a hardened layer and a low reflection layer.

10. The display device of claim 1, further comprising a protecting plate located on a surface on a side of the polarizer sheet apart from the display panel.

11. The display device of claim 10, wherein the protecting plate is a glass plate.

12. A manufacturing method of a display device, comprising:
forming an optical functional layer on a surface of a side of a polarizer sheet; and
attaching the side of the polarizer sheet that is formed with the optical functional layer to a surface of a display panel.

13. The manufacturing method of the display device of claim 12, wherein the polarizer sheet comprises a polarizing layer and protecting layers on both sides of the polarizing layer, and forming the optical functional layer on the surface of the side of the polarizer sheet comprises:
patterning a surface of the protecting layer on one side of the polarizer sheet to roughen the surface, thereby obtaining the optical functional layer.

14. The manufacturing method of the display device of claim 12, wherein attaching the side of the polarizer sheet that is formed with the optical functional layer to the surface of the display panel comprises:
coating curable glue between the side of the polarizer sheet that is formed with the optical functional layer and the surface of the display panel and curing the curable glue with ultraviolet curing approach for attachment.

15. The manufacturing method of the display device of claim 12, wherein the optical functional layer comprises at least one of an anti-glare layer, a hardened layer and a low reflection layer.

16. A manufacturing method of a display device, comprising:
forming an optical functional layer on a surface on at least one side of a display panel; and
attaching the at least one side of the display panel that is formed with the optical functional layer to a surface of a polarizer sheet.

17. The manufacturing method of the display device of claim 16, wherein attaching the at least one side of the display panel that is formed with the optical functional layer to the surface of the polarizer sheet comprises:
coating curable glue between the at least one side of the display panel that is formed with the optical functional layer and the surface of the polarizer sheet and curing the curable glue with ultraviolet curing approach for attachment.

18. The manufacturing method of the display device of claim 16, wherein the optical functional layer comprises at least one of an anti-glare layer, a hardened layer and a low reflection layer.

19. The display device of claim 2, wherein the display panel is provided with a touch unit, the polarizer sheet and the optical functional layer on a light emitting side, and the touch unit is disposed between the optical functional layer and the display panel.

20. The display device of claim 3, wherein the display panel is provided with a touch unit, the polarizer sheet and the optical functional layer on a light emitting side, and the touch unit is disposed between the optical functional layer and the display panel.
